(19) United States
(12) Patent Application Publication
(10) Pub. No.: US 2018/0208458 A1
(43) Pub. Date: Jul. 26, 2018

(54) METHOD FOR MANUFACTURING A MICROELECTRONIC MEDIA SENSOR ASSEMBLY, AND MICROELECTRONIC MEDIA SENSOR ASSEMBLY

(71) Applicant: Robert Bosch GmbH, Stuttgart (DE)

(72) Inventor: Ralf Reichenbach, Esslingen (DE)

(21) Appl. No.: 15/745,765

(22) PCT Filed: May 25, 2016
(86) PCT No.: PCT/EP2016/061766

§ 371 Date: Jan. 18, 2018

(30) Foreign Application Priority Data
Jul. 24, 2015 (DE) 10 2015 213 999.9

(51) Int. Cl. B81B 7/00; B81B 3/00; B81C 1/00

(52) U.S. Cl. CPC B81B 7/007; B81B 3/0018; B81C 2203/0792; B81B 2201/0264; B81C 1/00301

(57) ABSTRACT

A manufacturing method for a microelectronic component assembly and a microelectronic component assembly. The manufacturing method includes providing a sensor having a first surface and a second surface opposite to the first surface, as well as at least one lateral surface, at least sections of the first surface including a detection surface. In a subsequent step, a sacrificial material is deposited onto the first surface of the sensor, at least some regions of the detection surface being covered by the sacrificial material, and the sacrificial material extending to the lateral surface of the sensor. A carrier having a mounting surface is then provided. Subsequently, the sensor is connected electrically on the carrier, the first surface of the sensor and the mounting surface of the carrier facing each other at a distance. Afterwards, the sacrificial material is removed, the detection surface becoming at least partially free of the sacrificial material.

### FIELD

The present invention relates to a method for manufacturing a microelectronic component assembly and a corresponding microelectronic component assembly.

### BACKGROUND INFORMATION

Microelectronic component assemblies, in particular, media sensors, include a cap having an opening; access of the surrounding atmosphere to a measuring element of the media sensor being possible via the opening of the cap. The media sensors are cemented onto or mounted to a carrier via a surface opposite to the cap or housing. In order to protect the measuring elements from the intrusion of water or dirt during a separating procedure of these packages, the openings of the cap are laminated, using an adhesive film, prior to the separation of strips.

However, with progressive miniaturization of such media sensor packages, manufacturing methods that dispense with a cap are necessary. In this connection, it is problematic that when there is no cap, the sensitive measuring elements may not be efficiently protected from environmental influences. This problem may occur, in particular, due to contact protection frames, or due to flip-chip mounting of the media sensor onto a carrier, the measuring element or the detection surface facing the mounting surface. However, in flip-chip mounting, a gap (“stand-off”) forms between the detection surface of the media sensor and the mounting surface of the carrier. This gap allows the detection surface to be freely accessible from the outside, and the detection surface may be damaged or soiled, in particular, during further processing.

German Patent Application No. DE 10 2009 057 697 A1 describes a method for manufacturing electrode layers for chemical media sensors.

### SUMMARY

The present invention provides a method for manufacturing a microelectronic component assembly and a corresponding microelectronic component assembly.

Advantageous further refinements of the present invention are described herein.

The present invention allows subsequent access to a detection surface of a sensor to be established, for example, after separation or surface mounting. With the aid of the method, described here, for manufacturing the microelectronic component, the detection surface is protected cost-effectively from damage or contamination prior to initial operation.

Although the method, described here, for manufacturing a microelectronic component assembly is described in light of one sensor and a carrier, the manufacturing method described here is also applicable for manufacturing microelectronic component assemblies including a plurality of sensors, which are mounted on a carrier.

According to one preferred further refinement of the present invention, the sacrificial material is removed during an additional baking step or a selective etching process. Thus, the sacrificial material may be removed in a simple and cost-effective manner, where the detection surface may be free of the sacrificial material. The additional baking step may occur, for example, in a temperature range of 180° C. to 200° C., over 60 minutes. During the baking step, the sacrificial material decomposes, for example, into the gas phase and, in particular, may be drawn off from or pumped out of a process chamber.

According to a further preferred refinement, the sacrificial material includes a thermally decomposable polymer. The thermally decomposable polymer may be, in particular, a TDP (thermal decomposable polymer). Consequently, after the sensor has been connected electrically to the mounting surface of the carrier, the sacrificial material may be removed particularly efficiently, in which case, in particular, materials for electrically connecting the sensor to the carrier are not damaged.

According to a further preferred refinement of the present invention, the sacrificial material includes a chemically decomposable polymer. Thus, a cost-effective, selective etching process may be used for removing the sacrificial material.

According to another preferred further refinement of the present invention, the carrier includes a laminate substrate or an integrated circuit. In this manner, the manufacturing method described here may be applied to a broad spectrum of carriers.

Another preferred further refinement provides for the carrier to include at least two vias, the vias extending from the mounting surface to a surface opposite to the mounting surface, and further soldering globules being situated on the surface, at least some regions of each of the further soldering globules being in contact with the vias. Thus, with the aid of the further soldering globules, the microelectronic component assembly may be built up further by surface mounting. In addition, several vias having corresponding, further soldering globules on the surface are possible.

According to another preferred further refinement of the present invention, the further soldering globules are situated on the mounting surface. Thus, with the aid of the further soldering globules, the microelectronic component assembly may be built up further by flip-chip mounting. In the flip-chip mounting, the further soldering globules are formed in such a manner, that after the flip-chip mounting, the sensor of the microelectronic component assembly is set apart from a further carrier in a vertical direction.

According to another preferred further refinement of the present invention, the sacrificial material is patterned, using photolithography. The patterning by photolithography preferably occurs prior to the electrical connecting of the sensor to the mounting surface of the carrier. In other words, the sacrificial material is patterned by photolithography prior to the flip-chip mounting. In particular, the patterning may be carried out in such a manner, that the sacrificial material extends to the lateral surfaces of the sensor and ends flush with the lateral surfaces. Alternatively, during a separating procedure of the carrier between two adjacent sensors, the sacrificial material may end flush with flanks or edges of the lateral surface of the sensor; prior to the separating procedure, the sacrificial material being able to be formed continuously, at least between two sensors. In addition, the sacrificial material is patterned in such a manner, that the detection surface may be covered completely by the sacrificial material. Furthermore, for example, the detection surface may additionally be protected from high temperatures and etching agents by silicon nitride passivation, prior to depositing the sacrificial material. Silicon nitride passivation is carried out, in particular, in sensors that are used for measuring pressure.

According to a preferred further refinement of the present invention, the electrical connecting is carried out with the aid of soldering globules and a mechanically stabilizing material. For example, the mechanically stabilizing material may be understood to be an underfill material. In particular, the underfill material is used for providing a stable electrical connection in view of the different coefficients of thermal expansion of the sensor and the substrate.

According to another preferred further refinement of the present invention, the electrical connecting is carried out, using a continuous material bonding method. Thus, in particular, the electrical connecting may be carried out in a timesaving manner. In addition, in the case of the continuous material bonding method, an additional underfill material may be omitted.

According to another preferred further refinement of the present invention, the continuous material bonding method is based on an ICA or NCA method. The ICA method (isotropic conductive adhesive) is based on an isotropic conductive adhesive. The NCA method (non-conductive adhesive) is based on a non-conductive adhesive and makes use of so-called stud bumps for electrical contacting, the stud bumps being able to include, in particular, a gold wire. This allows timesaving electrical connecting to be implemented; generally, the temperatures required for curing being less than in the case of soldering, which means that the thermal loading for the microelectronic component assembly may be reduced.

The features, described here, of the method for manufacturing the microelectronic component assembly also correspondingly apply to the microelectronic component assembly, and vice versa.

### BRIEF DESCRIPTION OF THE DRAWINGS

Additional features and advantages of the present invention are explained below in light of specific embodiments, with reference to the figures.

FIG. 1 shows a schematic vertical cross-sectional view for explaining a microelectronic component assembly and a corresponding manufacturing method according to a first specific embodiment of the present invention.

FIG. 2 shows a schematic vertical cross-sectional view for explaining a microelectronic component assembly and a corresponding manufacturing method according to a second specific embodiment of the present invention.

FIG. 3 shows a schematic top view of a first surface of a sensor, in order to explain a method for manufacturing the microelectronic component assembly.

FIG. 4 shows a further schematic top view for explaining the method for manufacturing the microelectronic component assembly.

FIG. 5 shows a further schematic vertical cross-sectional view for explaining the method for manufacturing the microelectronic component assembly according to FIG. 4.

FIG. 6 shows a flow chart for explaining a sequence of the manufacturing method.

### DETAILED DESCRIPTION OF EXAMPLE EMBODIMENTS

In the figures, the same reference symbols denote identical or functionally equivalent elements.

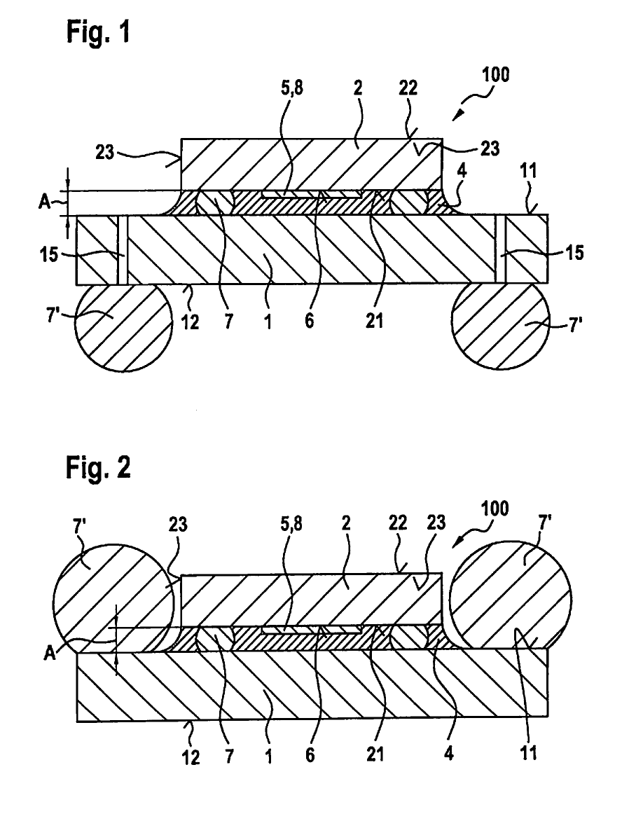

FIG. 1 shows a schematic vertical cross-sectional view for explaining a microelectronic component assembly and a corresponding manufacturing method according to a first specific embodiment of the present invention.

In FIG. 1, reference numeral 100 denotes a microelectronic component assembly including a sensor 2, the sensor 2 having a detection surface 6. In addition, a carrier 1 including a mounting surface 11 is shown in FIG. 1; with the aid of a mounting and connection device, sensor 2 being mounted on carrier 1 in such a manner, that detection surface 6 lies opposite to mounting surface 11, and an access 5 to detection surface 6 is present between detection surface 6 and mounting surface 11; at least some regions of detection surface 6 being exposed via access 5, and at least some regions of access 5 being free of a material of the mounting and connection device.

In this case, the mounting and connection device may be based on soldering globules 7 and a mechanically stabilizing material 4. Alternatively, the mounting and connection device may be based on a continuous material bonding method.

The microelectronic component assembly 100 shown in FIG. 1 may be manufactured, using a manufacturing method. In this connection, a sensor 2 having a surface 21, a second surface 22 opposite to first surface 21, and at least one lateral surface 23, is provided; at least sections of first surface 21 including a detection surface 6. For example, detection surface 6 may have a rectangular shape and be situated centrally on first surface 21. In particular, detection surface 6 may be intended for detecting pressure, moisture and/or gases, and may be part of a measuring element of sensor 2. In other words, the sensor 2 described here may be a media sensor.

In a subsequent step of the manufacturing method, a sacrificial material 8 is deposited on first surface 21 of sensor 2; at least some regions of detection surface 6 being covered by the sacrificial material, and sacrificial material 8 extending to at least one of the lateral surfaces 23 of sensor 2. For example, in this method step, sacrificial material 8 may cover the entire first surface 21 of sensor 2; sacrificial material 8 being able to be patterned by photolithography in such a manner, that sacrificial material 8 extends to two opposite lateral surfaces 23 and ends flush with the edges or flanks of lateral surfaces 23. In particular, the patterning by photolithography may expose regions, which may be intended for electrically connecting the sensor to mounting surface 11 of carrier 1.

In a subsequent method step, a carrier 1 having a mounting surface 11 is provided.

In a following method step, sensor 2 is electrically connected on carrier 1, first surface 21 of sensor 2 and mounting surface 11 of carrier 1 facing each other at a distance A, which is represented by the double arrow in FIG. 1; and in a final method step, sacrificial material 8 is removed, detection surface 6 becoming at least partially free of sacrificial material 8.

In FIG. 1, reference character 8 denotes the sacrificial material, which may be present in access 5 prior to the removal. That is, after the removal of sacrificial material 8, access 5 and detection surface 6 may be at least regionally free of the material of the mounting and detection device. The microelectronic component assembly 100 shown in FIG. 1 is based on electrical connecting with the aid of soldering globules 7 and a mechanically stabilizing material 4. Alternatively, the electrical connecting may also be accomplished, using a continuous material bonding method. In particular, ICA or NCA methods may be used for this.

The carrier 1 having mounting surface 11 may include an integrated circuit, the electrical connecting being able to be carried out with the aid of soldering globules 7, or alternatively, using the continuous material bonding method described here.

Carrier 1 may include at least two electrical through-contacts or vias 15. In this case, vias 15 extend from mounting surface 11 to a surface 12 opposite to mounting surface 11. Further soldering globules 7′ are situated on surface 12, further soldering globules 7′ being at least regionally in contact with vias 15. As shown in FIG. 1, vias 15, as well as further soldering globules 7′, are set apart laterally from sensor 2. Using further soldering globules 7′ on surface 12, microelectronic component assembly 100 may be built up further in a simple manner.

FIG. 2 shows a schematic vertical cross-sectional view for explaining a microelectronic component assembly and a corresponding manufacturing method according to a second specific embodiment of the present invention.

The microelectronic component assembly 100 shown in FIG. 2 is based on the microelectronic component assembly 100 shown in FIG. 1, with the exception that further soldering globules 7′ are situated on mounting surface 11 of carrier 1, and therefore, vias are not necessary. In other words, soldering globules 7′ and sensor 2 are situated on mounting surface 11, as shown in FIG. 2, the soldering globules each being set apart laterally from sensor 2. Thus, once more, microelectronic component assembly 100 may be built up further, using flip-chip mounting. In addition, vertical integration of microelectronic component assembly 100 may be carried out in a simplified manner.

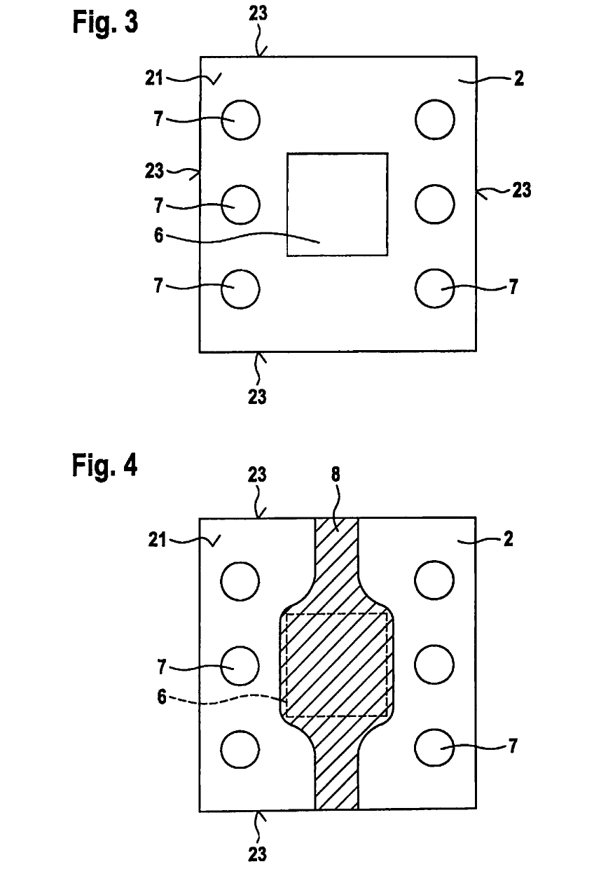

FIG. 3 shows a schematic top view of a first surface of a sensor, in order to explain a method for manufacturing the microelectronic component assembly.

In FIG. 3, reference character 21 denotes the first surface of sensor 2, and reference character 23 denotes corresponding lateral surfaces of sensor 2. As shown in FIG. 2, detection surface 6 may have a rectangular shape and be formed centrally on first surface 21. In addition, it is possible for surface 21 to have a plurality of detection surfaces 6, through which, in particular, a sensitivity of sensor 2 may be increased. In particular, detection surface 6 may be a part of a measuring element of sensor 2. As shown in FIG. 2, soldering globules 7 may be positioned in parallel with two opposite lateral surfaces 23 of sensor 2. A region intended for forming opening 5 is preferably free of locations, which are provided for connecting sensor 2 electrically to mounting surface 11 of carrier 1. In other words, the regions or region, on which sacrificial material 8 is deposited, are/is free of electrical connecting points.

FIG. 4 shows a further schematic top view for explaining the method for manufacturing the microelectronic component assembly.

FIG. 4 is based on the top view of first surface 21 of sensor 2 shown in FIG. 3, with the exception that sacrificial material 8, which may be patterned by photolithography, covers detection surface 6. In addition, sacrificial material 8 is patterned in such a manner, that sacrificial material 8 terminates flush with lateral surfaces 23 of sensor 2. For example, the sacrificial material may be formed in the shape of a strip, the ends of the strip terminating flush with lateral surfaces 23 of sensor 2. Alternatively, it would be possible for the sacrificial material to be patterned in such a manner, that the sacrificial material is patterned in the shape of a cross. In this case, soldering globules 7 are each formed correspondingly in the corner regions of first surface 21 of sensor 2.

In a later method step, sacrificial layer material 8 is removed at least partially from detection surface 6.

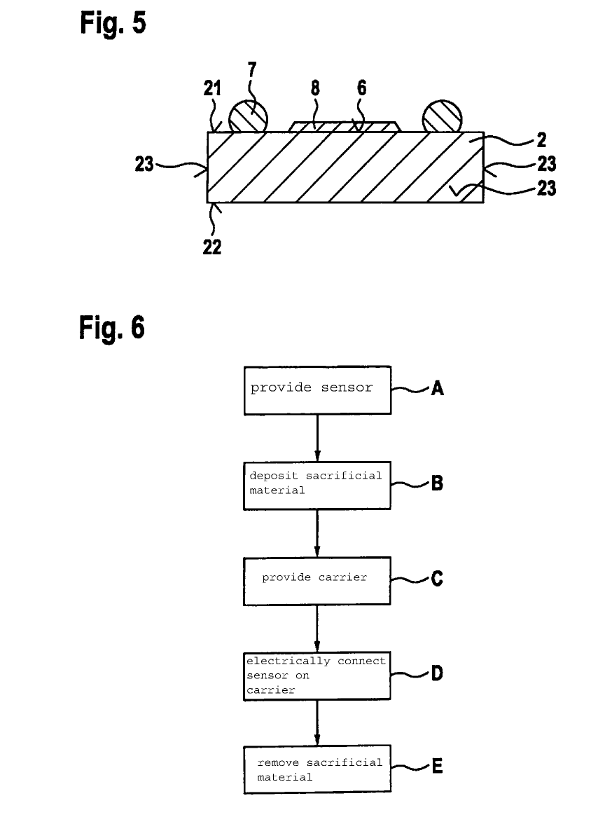

FIG. 5 shows a further schematic vertical cross-sectional view for explaining the method for manufacturing the microelectronic component assembly according to FIG. 4.

FIG. 5 shows a schematic side view of sensor 2 prior to the flip-chip mounting of sensor 2 onto mounting surface 11 of carrier 1. As shown in FIG. 5, soldering globules 7 are formed in such a manner, that after substrate 2 is mounted onto mounting surface 11 of carrier 1, first surface 21 of sensor 2 and mounting surface 11 of carrier 1 face each other at a distance A (cf. FIG. 1).

FIG. 6 shows a flow chart for explaining a sequence of the manufacturing method.

As shown in FIG. 6, the method for manufacturing microelectronic component assembly 100 includes steps A through E, according to which, in step A, a sensor 2 having a first surface 21 and a second surface 22 opposite to first surface 21, as well as at least one lateral surface 23, is provided; at least sections of first surface 21 including a detection surface 6. In a subsequent step B, a sacrificial material 8 is deposited onto first surface 21 of sensor 2, at least some regions of detection surface 6 being covered by sacrificial material 8, and sacrificial material 8 extending to lateral surface 23 of sensor 2. In step C, a carrier 1 having a mounting surface 11 is provided. Subsequently, in step D, sensor 2 is connected electrically on carrier 1, first surface 21 of sensor 2 and mounting surface 11 of carrier 1 facing each other at a distance A. Afterwards, in step E, sacrificial material 8 is removed, detection surface 6 becoming at least partially free of sacrificial material 8.

In other words, sacrificial material 8 is selectively removed after the flip-chip mounting, the electrical connecting being able to be carried out by flip-chip mounting, using soldering globules 7 and mechanically stabilizing material 4, or using a continuous material bonding method.

In addition, steps A through E proceed in the order as shown in FIG. 6.

The embodiment of the sacrificial layer 8 up to lateral surface 23 is used, for example, to allow access for removing sacrificial layer 8 in the mounted state of sensor 2 on carrier 1. Consequently, this set-up allows lateral access to the sacrificial material, even after an underfilling, as is shown in FIGS. 1 and 2.

1-14. (canceled)

15. A method for manufacturing a microelectronic component assembly, comprising:
providing a sensor having a first surface, a second surface opposite to the first surface, and at least one lateral surface, at least sections of the first surface including at least one detection surface;
depositing a sacrificial material onto the first surface of the sensor, at least some regions of the at least one detection surface being covered by the sacrificial material, and the sacrificial material extending to the lateral surface of the sensor;
providing a carrier having a mounting surface;
electrically connecting the sensor to the carrier, the first surface of the sensor and the mounting surface of the carrier facing each other at a distance; and
removing the sacrificial material, the detection surface becoming at least partially free of the sacrificial material.

16. The manufacturing method as recited in claim 15, wherein the sacrificial material is removed during an additional baking step or a selective etching process.

17. The manufacturing method as recited in claim 15, wherein the sacrificial material includes a thermally decomposable polymer.

18. The manufacturing method as recited in claim 15, wherein the sacrificial material includes a chemically decomposable material.

19. The manufacturing method as recited in claim 15, wherein the carrier includes one of a laminate substrate or an integrated circuit.

20. The manufacturing method as recited in claim 19, wherein the carrier includes at least two vias, the vias extend from the mounting surface to a surface opposite to the mounting surface, and further soldering globules are situated on the surface, and the further soldering globules are each at least regionally in contact with the respective vias.

21. The manufacturing method as recited in claim 19, wherein the further soldering globules are situated on the mounting surface.

22. The manufacturing method as recited in claim 19, wherein the sacrificial material is patterned by photolithography.

23. The manufacturing method as recited in claim 15, wherein the electrical connecting is carried out using soldering globules and a mechanically stabilizing material.

24. The manufacturing method as recited in claim 15, wherein the electrical connecting is carried out using a continuous material bonding method.

25. The manufacturing method as recited in claim 24, wherein the continuous material bonding method is based on an ICA or NCA method.

26. A microelectronic component assembly, comprising:
a sensor having at least one detection surface; and
a carrier having a mounting surface;
wherein, with the aid of a mounting and connection device, the sensor is mounted on the carrier in such a manner that the detection surface lies opposite to the mounting surface, and an access to the detection surface is present between the detection surface and the mounting surface, and at least some regions of the detection surface are exposed via the access, and at least some regions of the access are free of a material of the mounting and connection device.

27. The microelectronic component assembly as recited in claim 26, wherein the mounting and connection device is based on soldering globules and a mechanically stabilizing material.

28. The microelectronic component assembly as recited in claim 26, wherein the mounting and connection device is based on a continuous material bonding method.
